(19) United States
(12) Patent Application Publication
(10) Pub. No.: US 2022/0170843 A1
(43) Pub. Date: Jun. 2, 2022

(54) CONDUCTIVE NANOWIRE MEASUREMENT

(71) Applicant: Cambrios Film Solutions Corporation, Tortola (VG)

(72) Inventors: Jeff Alan WOLK, Half Moon Bay, CA (US); Michael Andrew SAPID, Mountain View, CA (US)

(21) Appl. No.: 17/600,726

(22) PCT Filed: Apr. 1, 2020
(86) PCT No.: PCT/US2020/026060

§ 371 Date: Oct. 1, 2021

Related U.S. Application Data
(60) Provisional application No. 62/828,667, filed on Apr. 3, 2019.

(51) Int. Cl. G01N 15/14; G01B 11/08; G01B 11/02; G01N 1/28; G06T 7/62

(52) U.S. Cl. CPC G01N 15/1475; G01B 11/08; G01N 2015/0038; G01N 1/2813; G06T 7/62; G01B 11/024

(57) ABSTRACT

A method of concurrently determining length and diameter of nanowires. Nanowires are provided onto a support. A chosen illumination of the nanowires on the support is provided. An image of the nanowires on the support is obtained. A length of each nanowire is calculated by an image processing program. A relative diameter of each nanowire is calculated based on an integrated intensity of light scattered per unit length from each nanowire.

### RELATED APPLICATION

This application claims priority to U.S. Provisional Application Ser. No. 62/828,667, titled “CONDUCTIVE NANOWIRE MEASUREMENT” and filed on Apr. 3, 2019, which is incorporated herein by reference.

### FIELD

This disclosure relates generally to length and diameter measurement of metal nanowires.

### BACKGROUND

Nanowires can be used within a transparent conductor (TC). Such TCs include optically-clear and electrically-conductive films. Silver nanowires (AgNWs) are an example nanowire. An example application for AgNWs is within TC layers in electronic devices, such as touch panels, photovoltaic cells, flat liquid crystal displays (LCD), organic light emitting diodes (OLED), etc. Various technologies have produced TCs based on one or more conductive media such as conductive nanowires. Generally, the conductive nanowires form a percolating network with long-range interconnectivity.

As the number of applications employing TCs continues to grow, improved production methods are required to satisfy the demand for conductive nanowires. Electrical and optical properties of a TC layer are strongly dependent on the physical dimensions of the conductive nanowires forming the percolating network. Conventional measurement methods do not allow for sufficient analysis of the physical dimensions of conductive nanowires.

### BRIEF SUMMARY

In accordance with an aspect, the present disclosure provides a method of concurrently determining length and diameter of nanowires. Nanowires are provided onto a support. A chosen illumination of the nanowires on the support is provided. An image of the nanowires on the support is obtained. A length of each nanowire is calculated by an image processing program. A relative diameter of each nanowire is calculated based on an integrated intensity of light scattered per unit length from each nanowire.

The above summary presents a simplified description in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### BRIEF DESCRIPTION OF THE DRAWINGS

While the techniques presented herein may be embodied in alternative forms, the particular embodiments illustrated in the drawings are only a few examples that are supplemental of the description provided herein. These embodiments are not to be interpreted in a limiting manner, such as limiting the claims appended hereto.

The disclosed subject matter may take physical form in certain parts and arrangement of parts, embodiments of which will be described in detail in this specification and illustrated in the accompanying drawings which form a part hereof and wherein:

FIG. 1 is a flowchart of an example method in accordance with an aspect of the present disclosure.

FIGS. 2A and 2B combine to provide an image of an example computer routine that can be utilized within the method of FIG. 1.

FIG. 3 is a plot of length vs diameter of an example batch of nanowires.

FIG. 4 is a plot of length vs relative diameter of another example batch of nanowires.

FIG. 5 is a histogram showing frequency of occurrence of nanowire lengths within the example batch plotted in FIG. 4, using three methods of length determination.

FIGS. 6A and 6B are histograms showing frequency of occurrence of nanowire lengths within an example batch of nanowires, showing some variation based upon illumination intensity.

FIG. 7 is a histogram showing frequency of occurrence of nanowire lengths within an example batch of nanowires.

FIG. 8 is a plot of diameter, in relative units, vs length for an example batch of nanowires.

FIGS. 9A and 9B are plots of diameter, in relative units, vs length for an example batch of nanowires, showing some variation based upon illumination intensity.

FIG. 10 is a plot of diameter, in relative units, vs length for an example batch of nanowires.

FIG. 11 is a plot of frequency of occurrence of diameter for the example batch plotted in FIG. 8.

FIG. 12 is a plot of frequency of occurrence of diameter for the example batch plotted in FIG. 10.

FIGS. 13A-13B are plots of frequency of occurrence of diameter for the example batch plotted in FIGS. 9A and 9B, showing some variation based upon illumination intensity.

FIG. 14 is a plot showing example relative light intensity as a fraction of the full intensity vs microscope slider setting.

FIG. 15 is a plot of a scaling factor ratio vs nanowire diameter.

FIGS. 16A to 16D are plots of frequency of occurrence vs scaled diameter data.

FIGS. 17A to 17D are histograms showing frequency of occurrence of nanowire lengths within example batches of nanowires.

FIGS. 18A to 18D are plots of diameter vs length for the example batches of nanowires presented within FIGS. 17A to 17D.

FIGS. 19A and 19B are plots of frequency of occurrence of diameter for the example batch plotted in FIG. 18A to 18D.

FIG. 20 is an image of an example spin coater that can be used in conjunction with a method of the present disclosure.

FIG. 21 an image of typical nanowires provided via the spin coater of FIG. 20.

FIG. 22 is an image of a microscope that can be used in conjunction with a method of the present disclosure.

### DETAILED DESCRIPTION

Subject matter will now be described more fully hereinafter with reference to the accompanying drawings, which form a part hereof, and which show, by way of illustration, specific example embodiments. This description is not intended as an extensive or detailed discussion of known concepts. Details that are known generally to those of ordinary skill in the relevant art may have been omitted, or may be handled in summary fashion.

Certain terminology is used herein for convenience only and is not to be taken as a limitation on the disclosed subject matter. Relative language used herein is best understood with reference to the drawings, in which like numerals are used to identify like or similar items. Further, in the drawings, certain features may be shown in somewhat schematic form.

The following subject matter may be embodied in a variety of different forms, such as methods, devices, components, and/or systems. Accordingly, this subject matter is not intended to be construed as limited to any illustrative embodiments set forth herein as examples. Rather, the embodiments are provided herein merely to be illustrative. Such embodiments may, for example, take the form of hardware, software, firmware or any combination thereof.

Provided herein is a method of determining length and diameter of conductive nanowires. Such measurements occur concurrently, and optionally simultaneously. As used herein, “conductive nanowires” or “nanowires” generally refer to electrically conductive nano-sized wires, at least one dimension of which is less than 500 nm, or less than 250 nm, 100 nm, 50 nm, 25 nm or even less than 10 nm, for example. Typically, the nanowires are made of a metallic material, such as an elemental metal (e.g., transition metals) or a metal compound (e.g., metal oxide). The metallic material can also be a bimetallic material or a metal alloy, which comprises two or more types of metal. Suitable metals include, but are not limited to, silver, gold, copper, nickel, gold-plated silver, platinum and palladium.

The morphology of a given nanowire can be defined in a simplified fashion by its aspect ratio, which is the ratio of the length over the diameter of the nanowire. The anisotropic nanowire typically has a longitudinal axis along its length.

Nanowires typically refers to long, thin nanowires having aspect ratios of greater than 10, preferably greater than 50, and more preferably greater than 100. Typically, the nanowires are more than 500 nm, more than 1 μm, or more than 10 μm long. Although the present disclosure is applicable to variations, some discussions herein with be directed to silver nanowires (“AgNWs” or abbreviated simply as “NWs”) will be described as an example.

Electrical and optical properties of a transparent conductor (TC) layer are strongly dependent on the physical dimensions of nanowires—i.e. their length and diameter, and more generally, their aspect ratio. In general, networks comprised of nanowires with larger aspect ratios form conductive networks with superior optical properties; in particular lower haze. Because each nanowire can be considered a conductor, individual nanowire length and diameter will affect the overall nanowire network conductivity and, therefore, the final film conductivity. For example, as nanowires get longer, fewer are needed to make a conductive network; and as nanowires get thinner, nanowire resistance and resistivity increase—making the resulting film less conductive for a given number of nanowires.

Similarly, nanowire length and diameter will affect the optical transparency and light diffusion (haze) of the TC layers. Nanowire networks are optically transparent because nanowires comprise a very small fraction of the film. However, the nanowires absorb and scatter light, so nanowire length and diameter will, in large part, determine optical transparency and haze for a conductive nanowire network. Generally, thinner nanowires result in reduced haze in TC layers—a desired property for electronic applications.

Furthermore, low aspect ratio nanowires (a byproduct of the synthesis process) in the TC layer result in added haze as these structures scatter light without contributing significantly to the conductivity of the network. Because synthetic methods for preparing metal nanowires typically produce a composition that includes a range of nanowire morphologies, both desirable and undesirable, there is a need to purify such a composition to promote retention of high aspect ratio nanowires. The retained nanowires can be used to form TCs having desired electrical and optical properties.

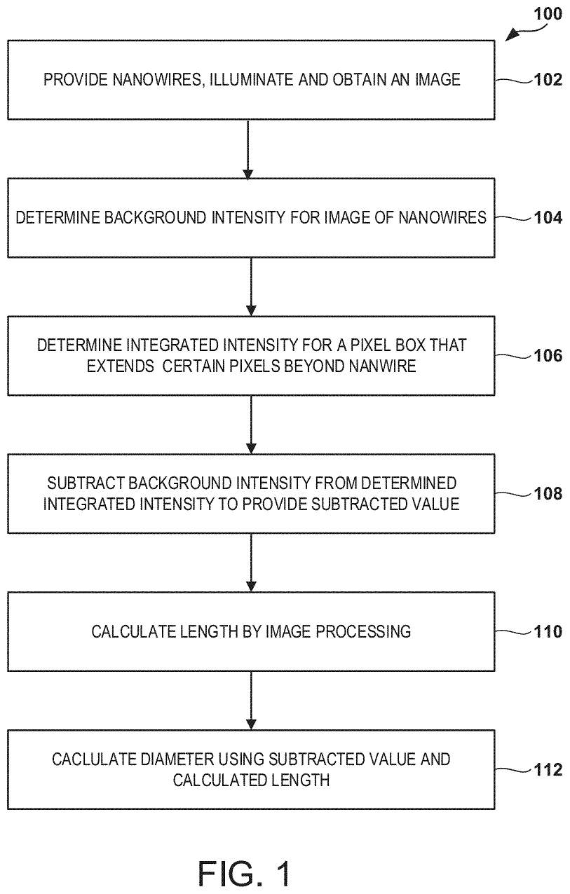

In one general example, a method 100 (FIG. 1) of determining length and diameter of conductive nanowires can include: providing the nanowires onto a support (see step 102), providing a chosen illumination of the nanowires on the support (see step 102), obtaining an image of the nanowires on the support (see step 102, at least these steps can be considered initial preparation and can be grouped into an overall preparation step as shown within FIG. 1), optionally determining a background intensity value for the image of the nanowires (see step 104), optionally determining an integrated intensity value for each nanowire for a pixel box that extends a selected number of pixels beyond the respective nanowire (see step 106), optionally subtracting the background intensity from the determined integrated intensity to determine a subtracted value for each nanowire (see step 108), calculating a length of each nanowire by an image processing program (see step 110), and calculating a relative diameter of each nanowire using the subtracted value and the calculated length of the respective nanowire and by using an equation (see step 112). Within one example equation, the equation is the following:

relative diameter α(subtracted value/length)ⁿ Equation:

wherein the value of n is within a range of ⅕ to ½. Within an example, the value of n is approximately ⅓, and within a specific example the value of n is ⅓.

It is to be noted that the above method could be performed using various structure(s)/device(s). Within an example, the method is performed using a spin coater and a microscope, with the microscope in reflected light, dark field mode.

It is to be appreciated that variants and/or additional details can be included within the method within the scope of this disclosure.

As some examples, this disclosure presents the results for a few trials of software written for a platform such as MATLAB, for example, to concurrently or simultaneously measure length and diameter of nanowire systems. An example method for carrying out this analysis can be as follows in the numbered steps of 1 to 4.

1) Spin a sample (which depending on Silver/Ag nanowire concentration and nanowire length is roughly comprised of 0.1-0.6 μl of sample in 6.5 ml of IPA) at 1000 RPM for 30 s on Silicon/Si wafers, the images of which provide better contrast than those taken for nanowires spun on glass samples.

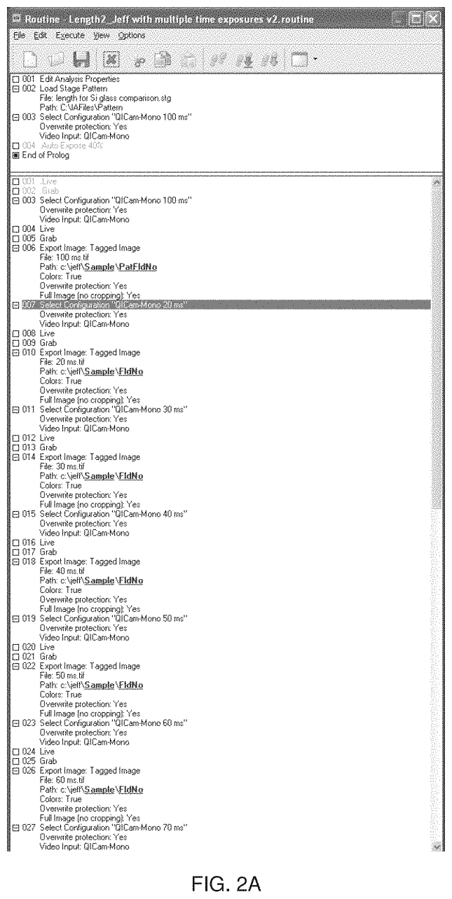

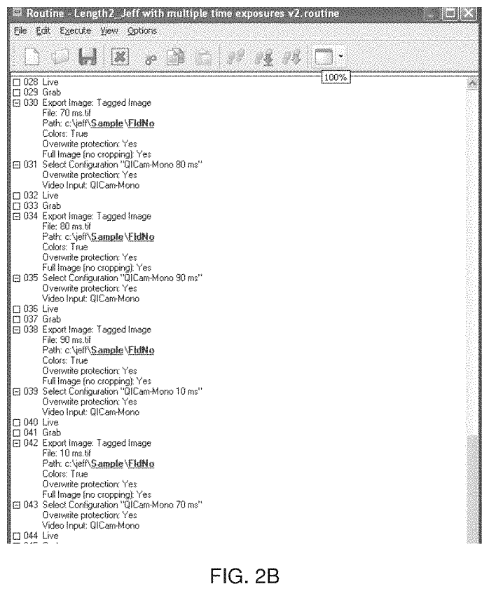

2) Use a computer routine, such as an example routine, which is shown within FIGS. 2A and 2B. It is to be understood that the specific computer routine need not be a specific limitation upon the disclosure. Other/different computer routines could be written and/or used. The person of ordinary skill in the art will appreciate such other/different computer routines could be written and/or used.

The utilized example routine takes 144 images at 500× magnification. But instead of simply analyzing the length of the identified nanowires, this example routine takes and saves the images/photographs (e.g., in TIF format) using integration times ranging from 10-100 ms in steps of 10 ms.

3) The images are then analyzed using a new image processing program that has been written in MATLAB. This software calculates the length of all the nanowires, and also calculates the diameter according to the following protocol (alphabetic steps a to d):

a) Determine the background intensity in the image.

b) Determine the integrated intensity in a box which extends ten pixels beyond the limits for each given nanowire. Subtract out the background intensity from this total.

c) Also, as an option, reject all nanowires which: 1) have oversaturated pixels, 2) are too close to other wires such that their integrated intensity includes contributions from other wires, 3) have an aspect ratio less than three, or 4) intersect with the edge of the image. It is to be appreciated that the need to reject nanowires is dependent upon the circumstances of the testing. It is contemplated that the testing circumstances could be such that no rejection is needed. Moreover, it is to be appreciated that additional and/or different rejection criterial can be utilized. It is to be appreciated that such variations are within the scope of this disclosure.

d) Using the background-subtracted integrated intensity and length measured for the nanowires, calculate a relative diameter using the relationship to determine diameter (also known as “d”):

diameter α(Intensity/Length)^{1/3}

again, ⅓ is one example value for the exponent.

4) The final output of the software can be a plot and a spreadsheet containing a listing of the length, intensities per unit length, and diameters of each nanowire which meet the criteria listed in step 3c above, as needed and/or as additional/different criteria are utilized.

Again, the above presents an example. It is possible to have variations, such as varying the exponent with the equation within a range of ⅕ to ½. A purpose of performing the above is to obtain an understanding/information regarding length and diameter of nanowires.

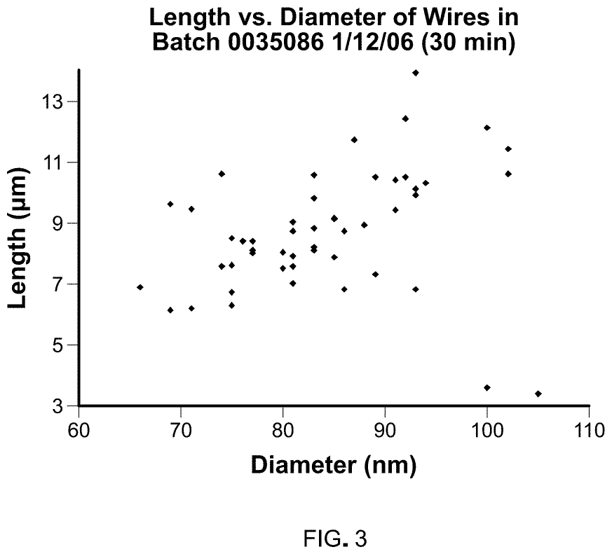

It would be logical to reflect upon the usefulness of the method provided by the present disclosure. As an example, see FIG. 3 which is a plot showing lengths and diameters of a sample (e.g., batch 0035086). Such simply shows that lengths and diameters within a batch do vary. Note that there is correlation between length and diameter in that both values tend to rise together. However, FIG. 3 is an example of data taken before the technique according to the present disclosure was available. To create the graph of FIG. 3, the length and diameter of each nanowire was individually measured using a scanning electron microscope (SEM). Such is an extremely laborious process, and is part of the motivation for developing this new technique.

Turning now to some studied example batches that were used to help develop the technique of the present disclosure, the following is provided with the understanding that the data was taken before the technique according to the present disclosure was available (i.e., the length and diameter of each nanowire was individually measured). Their morphologies are determined, and some of the information is tabulated in Table 1. Such is provided to develop, and then verify the usefulness of, the technique of the present disclosure.

TABLE 1

| | Length | St. Dev. Length | Diameter | St. Dev. Diam. |
|---|---|---|---|---|
| Batch | (μm) | (μm) | (nm) | (nm) |
| 14L0983 PR | 14.0 | 5.9 | 23.7 | 3.1 |
| 15A007 PR | 13.0 | 6.1 | 23.5 | 3.4 |
| 268036D PR | 8.4 | 3.4 | 46.4 | 7.5 |

The first batch to be analyzed using the above process was batch 14K0983PR. This batch has a diameter of 23.7 nm. One very interesting outcome of the analysis is that the present analysis affords a way to determine the correlation between length and diameter since both quantities are determined for individual wires. The above stated equation (i.e., diameter α (Intensity/Length)^{1/3}) is the result of theoretical modeling performed by the inventors. Moreover, such equation was confirmed by way of testing of the equation versus experimental data. So, one purpose of the testing that was conducted was to validate the method or see if some modification of the equation was required to reach a better agreement.

As a first posit, it was determined, assuming the truth of the example equation:

diameter α(Intensity/Length)^{1/3}

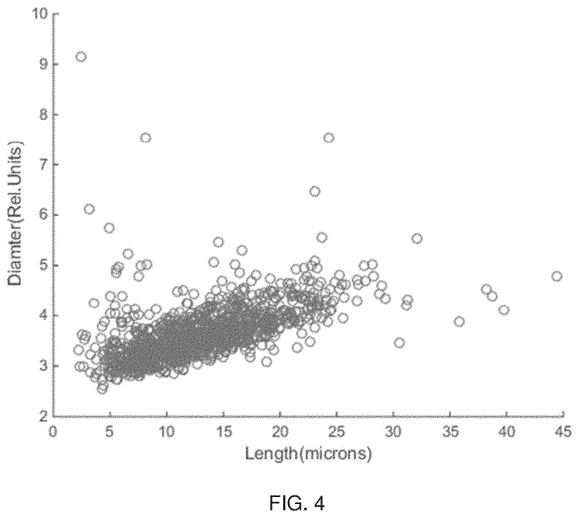

There does appear to be a correlation between length and diameter. FIG. 4 is a plot of length vs. diameter results for batch 14L0983 from Table 1.

During this analysis there were three separate determinations made of sample length. The first determination was using the method that had previously been determined for measuring the length of nanowires on Si wafers, which is a slight modification of the algorithm for samples prepared on glass substrates. In the past this has been shown to correlate very well with results measured on glass. The second was the length measurement done as part of the MATLAB analysis routine, which is the measurement relevant for this technique. The third determination was via a standard method (e.g., performing image analysis of dark field micrographs (pictures) of nanowires on glass rather than Si). Given that we are determining intensity per unit length to calculate nanowire diameter, the determination of length is important.

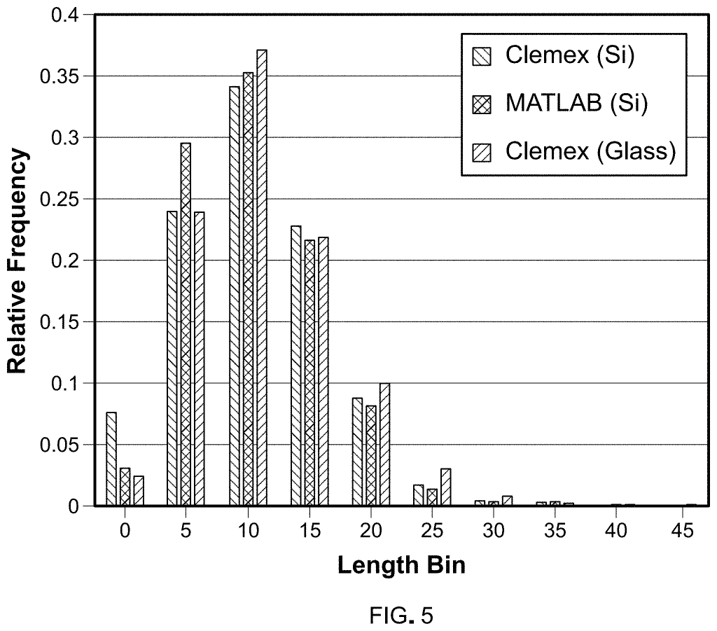

A histogram plot that shows comparison of all three of these length determinations in provided in FIG. 5 for length measurements carried out on batch 14L0983PR. For this histogram (FIG. 5) and all of the histogram plots within the figures, at each indicated length bin there three possible data presentations: CLEMEX® (Si), MATLAB (Si) and CLEMEX® (Glass), sequentially left to right if present. It is to be noted that this histogram (FIG. 5) should be read such that the first peaks correspond to nanowires in the 0-5 μm range, the next in the 5-10 μm range, etc. Table 2, below, provides results of nanowire length measurement by various methods for batch 14L0983PR.

TABLE 2

| Batch | Number of | Length | St. Dev. Length |
|---|---|---|---|
| 14L0983PR | nanowires | (μm) | (μm) |
| CLEMEX ® | 2762 | 14.0 | 5.9 |
| (Glass) | | | |
| CLEMEX ® | 1096 | 13.0 | 5.7 |
| (Si) | | | |
| MATLAB (Si) | 1158 | 13.0 | 5.5 |

It is to be noted that: 1) there are a different amount of wires for the Si results, even though these were carried out simultaneously, and 2), that the relative amounts of wires differ in the 0-5 and 5-10 μm ranges. The CLEMEX® (Si) results were tabulated for a photograph taken with an integration time of 70 ms, while the MATLAB results were taken for times up to 100 ms. This means that wires scattering less light could have been missed in the CLEMEX® analysis. Considering the previously discussed figures, however, one would think this would mean that the CLEMEX® (Si) results would have fewer short wires in the shortest category. However, such is not the case. One could explain that by positing that some dim wires were counted as multiple wires due to the poor contrast in the CLEMEX® analysis. Also, the thresholding method is different for the two software analyses, so this could be related to the observed differences as well. In the longer length sections of the histogram the distributions look very similar.

It is also to be noted that the older CLEMEX® (Glass) data differs mostly in showing a greater preponderance of longer wires. This could result from either 1) an actual change in the relative number of longer wires, or 2) a greater number of counted wires which actually consist of two adjacent wires since their density is so much higher for this data, or 3) the non-observance of shorter, thinner (and thus dimmer) wires. It is to be again noted that in previous work comparing the data on Si wafers and glass the results were essentially the same. The only difference in the instrumentation for that work was that the integration time was 50 ms and the gain was 3000, whereas in this work the camera gain is set to 1500.

Two other batches have also been observed as part of this work. As such following are sample comparisons for them as well. But, before such discussion it would be prudent to discuss the circumstances under which the data was obtained. For the data on batch 268036D, the wires are fat and the scattering is strong. This resulted in the signal form the wires being saturated at many of the integration times being used. To avoid this situation, the intensity was set at 10 (the intensity was lowered and then increased until the 10 bar lighted on the intensity scale of the microscope) rather than the maximum intensity used for 14L0983. Using the THORLABS® photodiode detector we have measured this to correspond to a decrease in the intensity of the light by a factor of 2.1, which was later lowered to 1.90. The batch 15A007PR, was run at both maximum and lower intensity. So, there are three length measurements to compare for the batch 268036D and four measurements for 15A007PR.

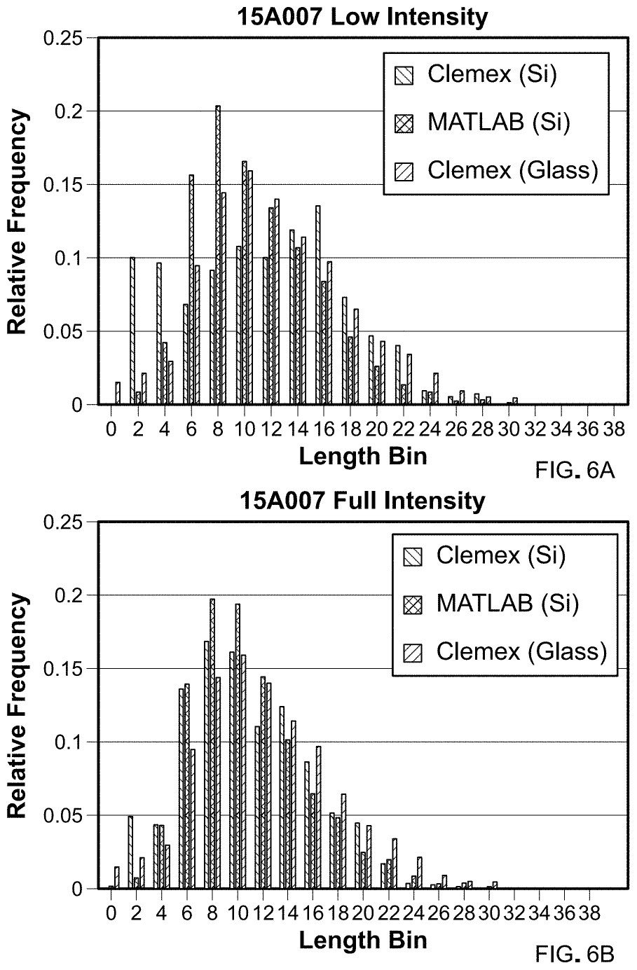

For the experiments on batch 15A007PR the CLEMEX® (Si) file and the MATLAB (Si) file were for different runs of the same sample. Data from such is shown in the histograms of FIGS. 6A and 6B, which show the same nanowire batch being run at two different intensity levels. Such can provide comparative information. It is to be noted that adjustment of illumination level may provide improved results. It is to be noted that these histograms (FIGS. 6A and 6B), and some following histograms, should be read such that the first peaks correspond to nanowires in the 0-2 μm range, the next in the 2-4 μm range, etc.

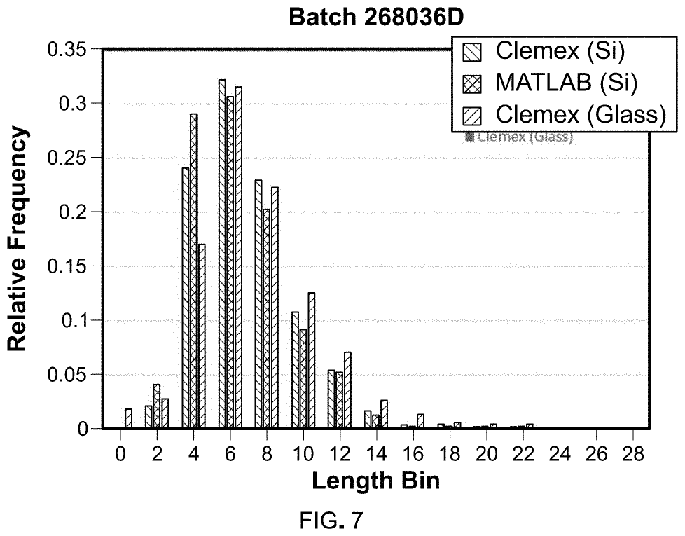

For the run of batch 268036D, there was fairly good agreement between the results on Si, and they are again shorter than the results found by CLEMEX® analysis on glass. The binning is also done more finely here due to both the desire for a finer distribution and the shorter average nanowire length. See the following Table 3, which presents the results of nanowire length measurement by various methods for batch 268036D. FIG. 7 is a histogram for length measurements carried out on batch 268036D. This histogram should be read such that the first peaks correspond to nanowires in the 0-2 μm range, the next in the 2-4 μm range, etc.

TABLE 3

| Batch | Number of | Length | St. Dev. Length |
|---|---|---|---|
| 268036D | nanowires | (μm) | (μm) |
| CLEMEX ® | 2381 | 8.4 | 3.4 |
| (Glass) | | | |
| CLEMEX ® | 777 | 7.9 | 2.7 |
| (Si) | | | |
| MATLAB (Si) | 792 | 7.50 | 2.6 |

Turning to an examination of the results for Batch 15A007 at both low and high intesnity. As mentioned, the results are listed and plotted as histograms within FIGS. 6A and 6B. Once again the results of the length measurement are in general shorter for the samples measured on Si and show a dearth of longer wires compared to the data taken on glass substrates. Based on the histogram information, the quality of the data for the low intensity CLEMEX® (Si) that length measurement should be discounted. So, while some issues with length measurement persist, it is important to keep in mind that a length measurment of 12 rather than 13 microns implies a change in (ΔI/I) of 8.3%, and thu a change in diameter of only 2.7%. This translates to about a 0.6 nm error for 23 nm diameter annowires. Table 4, following, provides the results of nanowire length measurement by various methods for batch 15A007 at low and full intensity.

TABLE 4

| | | Number of | | |
|---|---|---|---|---|
| Batch 15A007 | Light | nanowires | | St. Dev. |
| Low Intensity | Intensity | Analyzed | Length (μm) | Length (μm) |
| CLEMEX ® | NA | 2925 | 13.0 | 6.1 |
| (Glass) | | | | |
| CLEMEX ® (Si) | Low | 427 | 12.6 | 6.0 |
| MATLAB (Si) | Low | 1021 | 11.8 | 2.9 |
| CLEMEX ® (Si) | Full | 902 | 11.9 | 5.0 |
| MATLAB (Si) | Full | 851 | 11.9 | 3.7 |

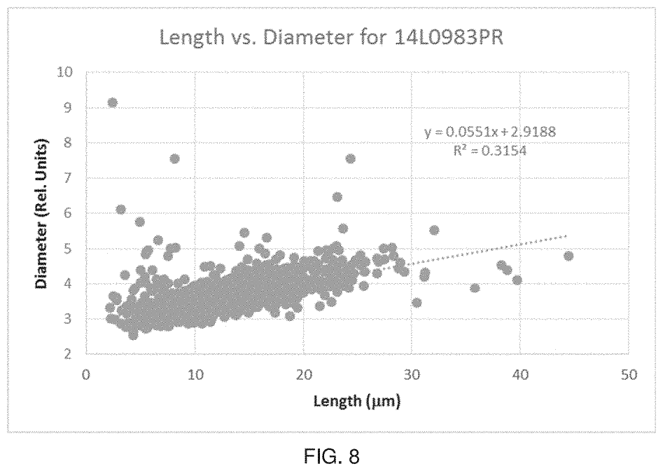

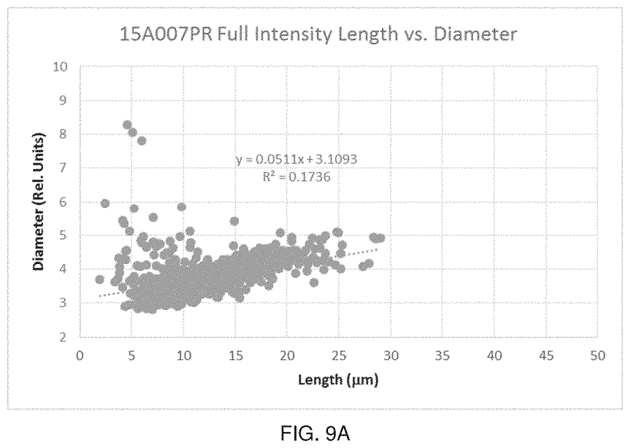

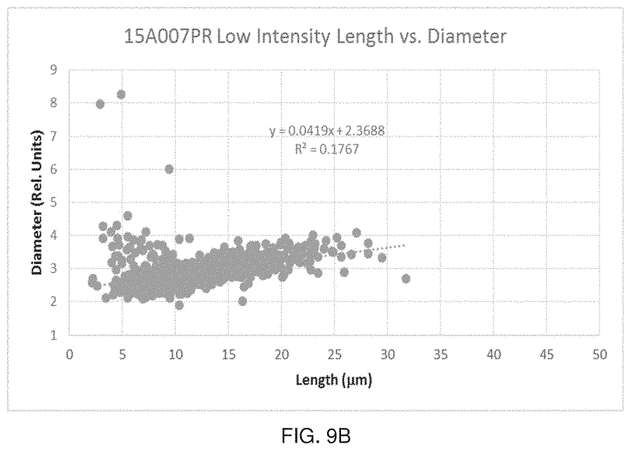

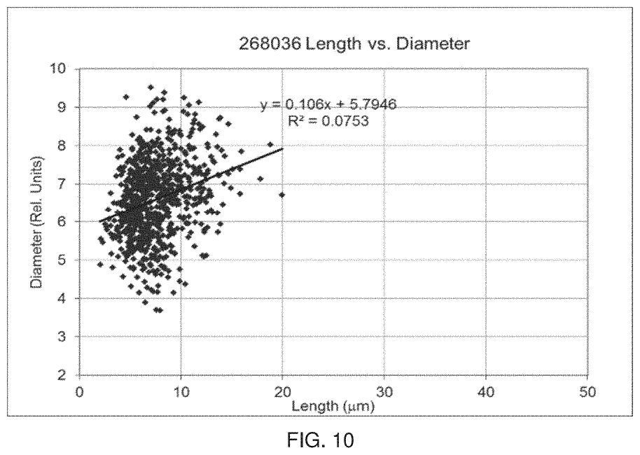

Now provided is a discussion of the calculations of the diameter for all of the nanowire batches measured. First, working in the arbitrary units of the quantity calculated by MATLAB (the cube root of the integrated intensity per unit length of the wires), we plot the results below. It can be seen that in all cases there is a definite correlation observed between length and diameter, though this correlation is weaker for the large diameter 268036D batch. See FIG. 8 regarding a plot of diameter (in relative units) versus length (in μm) for 14L0983PR, FIGS. 9A and 9B regarding plots of diameter (in relative units) versus length (in μm) for 15A007PR at full and low intensity, respectively, and FIG. 10 regarding a plot of diameter (in relative units) versus length (in μm) for 268036.

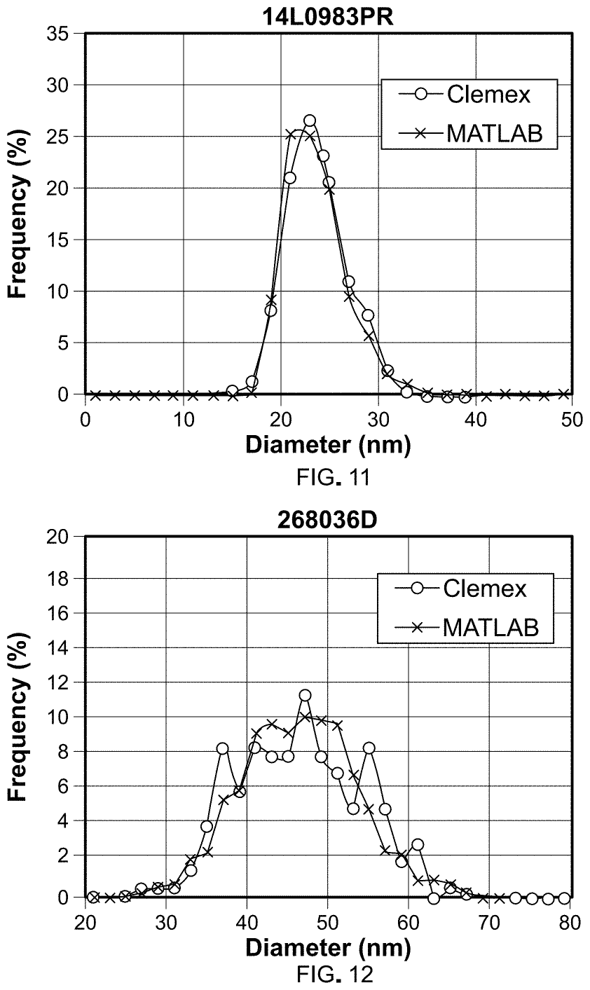

A comparison of the results of the measurements of diameter with the SEM is made against the results of the measurements of diameter made using MATLAB. It is to be noted that diameter data labeled “CLEMEX” is measured using an SEM, while that data labeled “MATLAB” is using the new technique. Attention is directed to FIGS. 11-13, 15, 16, and 19. Also it is to be noted that such a “Clemex” diameter measurement method is completely different than a “Clemex” length measurement method. For the diameter measurement method, the CLEMEX software is used to analyze SEM micrographs rather than dark field reflected light optical photographs as is the case for length measurements. The use of the software is very different in the two cases.

The main goal of this comparison is to determine whether or not a scale factor which relates the MATLAB diameter d_{ML} to the SEM diameter d_{SEM} and which is NOT a function of diameter is obtainable. The results are listed below. For the data taken at full intensity the results for d_{ML} are divided by (2.1)^{1/3} to take into account the difference in incoming light intensity. It can be seen that there is roughly 10% disagreement between the values of the ratio d_{SEM}/d_{ML} for the batches 14L0983 and 268036D, but that the agreement is much larger for both the low and high intensity data for 15A007. Table 4, above, also shows the larger number of wires capable of being analyzed by the new optical technique.

As an analysis of nanowire diameter data taken using both new technique and SEM, please see Table 5. Also, Table 6 provides the number of nanowires that were measured.

TABLE 5

| | Relative | | St. Dev. | Adjusted | Adjusted | | St. Dev. | |
|---|---|---|---|---|---|---|---|---|
| | Light | d_{ML} | d_{ML} | d_{ML} | St. Dev. d | d_{SEM} | d_{SEM} | Ratio |
| Batch | Intensity | (nm) | (nm) | (nm) | (nm) | (nm) | (nm) | d_{SEM}/d_{ML} |
| 14L0983 | 2.1 | 3.64 | 0.54 | 2.84 | 0.42 | 23.7 | 3.1 | 8.35 |
| 2615A007 | 2.1 | 3.72 | 0.55 | 2.90 | 0.43 | 23.5 | 3.4 | 8.10 |
| Full Intensity | | | | | | | | |
| 2615A007 | 1.0 | 2.86 | 0.45 | 2.86 | 0.45 | 23.5 | 3.4 | 8.22 |
| Low Intensity | | | | | | | | |
| 268036D | 1.0 | 6.6 | 1.0 | 6.6 | 1.0 | 46.4 | 7.3 | 7.03 |

TABLE 6

| | Number of | Number of |
|---|---|---|
| | nanowires | nanowires |
| | measured by | measured by |
| Batch | MATLAB | CLEMEX ® |
| 140983 | 1158 | 218 |
| 2615A007 | 1021 | 245 |
| Full | | |
| Intensity | | |
| 2615A007 | 851 | 245 |
| Low | | |
| Intensity | | |
| 268036D | 792 | 193 |

Next the scaling factors are determined by the above analysis to multiply the MATLAB diameter results and then compared the diameter distributions of the two techniques. These results are shown within FIGS. 11, 12, 13A and 13B. It is to be noted that the mean diameter for the CLEMEX® distribution and the MATLAB distribution are the same by virtue of a scaling factor. The point is to compare the shape of the distributions given this constraint. While the shape of the distribution matches very well for the 14L0983PR and 268036D batches the match is clearly inferior for both sets of 15A007 data. They have a more log-normal distribution than the SEM result. However, the disagreement is not too troublesome. In fact, given the log-normal distribution of the length and the correlated length and diameter one might expect a log-normal diameter distribution as well.

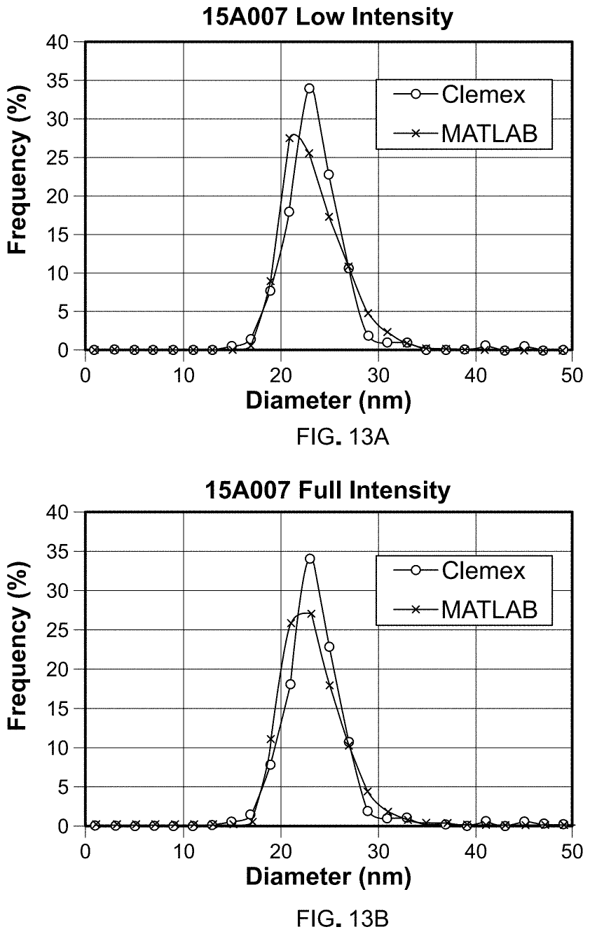

We now consider the scale factors for the different batches. We note that it is the same for the two batches with the same diameter, but is different for the larger diameter batch, 268036D. This could be a hint that the d³ dependence that might have been assumed may not be correct. This question can be settled by looking at more batches with intermediate diameter, and this is in fact the next set of experiments to be carried out. See for example FIGS. 11 and 12. It is to be noted that the change in light intensity seems to be taken care of correctly in that the constant was similar for the low and high intensity analyses of 15A007. See for example FIGS. 13A and 13B.

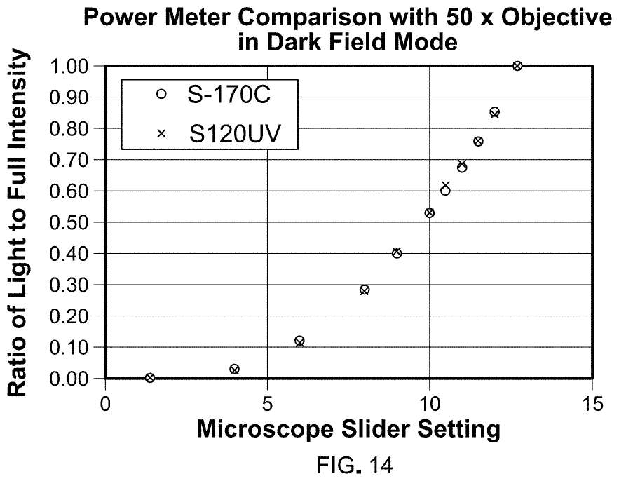

To increase the accuracy of and confidence in the intensity measurements, a light meter is used to make better measurement of the light intensity incident on the sample. To check on the values measured using the THORLABS® S120UV meter, a comparison was run between this meter and the new THORLABS® S-170C meter which is shaped like a slide, making it very easy to get reproducible data. The graph comparing the relative light intensity as a fraction of the full intensity, based upon microscope slider setting is shown in FIG. 14. So, such is a comparison of intensity data for the old and new THORLABS® power meters. There are slight differences, but the data from the two meters compares very well. In the next set of comparisons that will be discussed the values were adjusted to be those measured using the new S-170C meter. In the future this meter can be used to measure the power coming from the objective at the time of measurement.

To test whether or not the ratio of the MATLAB diameter d_{ML} to the SEM diameter d_{SEM} was related to the type of wires being examined three additional wire batches were examined using the same methodology.

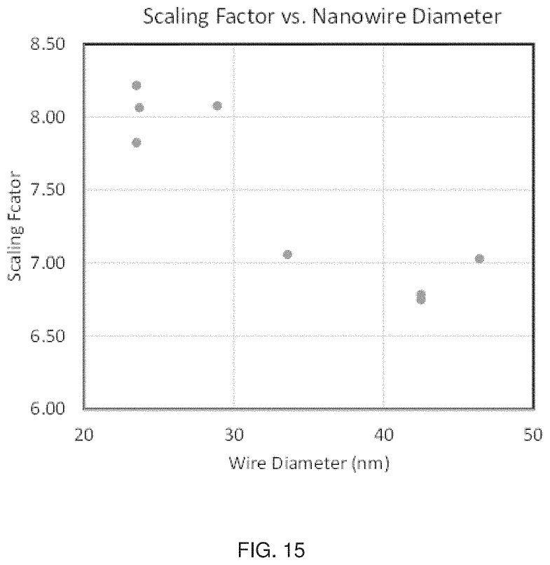

The new batches measured using MATLAB to analyze the diameter were 15A0014, 268036B, and 268036C. The data in Table 7, following, have been separated into two groups, one in which the ratio d_{ML}/d_{SEM} is roughly 8.0 and one for which this ratio is roughly 7.0. A plot of the ratio as a function of nanowire diameter is shown in FIG. 15. It is to be appreciated that FIG. 15 is a plotting of the scaling factor SF (d_{ML}/d_{SEM}) versus diameter.

TABLE 7

| | Relative | | St. Dev. | Adjusted | Adjusted | | St. Dev. | | |
|---|---|---|---|---|---|---|---|---|---|
| | Light | d_{ML} | d_{ML} | d_{ML} | St. Dev. d | d_{SEM} | d_{SEM} | Ratio | Slider |
| Batch | Intensity | (nm) | (nm) | (nm) | (nm) | (nm) | (nm) | d_{SEM}/d_{ML} | Intensity |
| 14L0938 | 1.9 | 3.64 | 0.54 | 2.94 | 0.35 | 23.7 | 3.1 | 8.06 | Full |
| 15A007 Full Intensity | 1.9 | 3.72 | 0.55 | 3.00 | 0.35 | 23.5 | 3.4 | 7.82 | Full |
| 15A007 Low Intensity | 1 | 2.86 | 0.45 | 2.86 | 0.32 | 23.5 | 3.4 | 8.22 | 10 |
| 15A014 intensity 11 | 1.31 | 3.91 | 0.69 | 3.58 | 0.44 | 28.9 | 4.3 | 8.08 | 11 |
| 268036D | 1 | 6.6 | 1 | 6.60 | 0.53 | 46.4 | 3.7 | 7.03 | 10 |
| 268036C Intensity 10 | 1 | 6.29 | 0.9 | 6.29 | 0.9 | 42.5 | 6.4 | 6.75 | 10 |
| 268036C Intensity 8 | 0.527 | 5.06 | 0.71 | 6.26 | 0.89 | 42.5 | 6.4 | 6.78 | 8 |
| 268036B Intensity 10 | 1 | 4.76 | 0.94 | 4.76 | 0.94 | 33.6 | 8.1 | 7.06 | 10 |

It was also examined whether or not using a different exponent in the relationship dαI^{1/3} would make the scaling factor similar for all batches, letting the exponent equal ⅕, 1/4.5, ¼, 1/3.5, 1/3.25, ⅓, 1/2.75, 1/2.5, and ½. None of these alternate exponents resulted in a constant scaling factor.

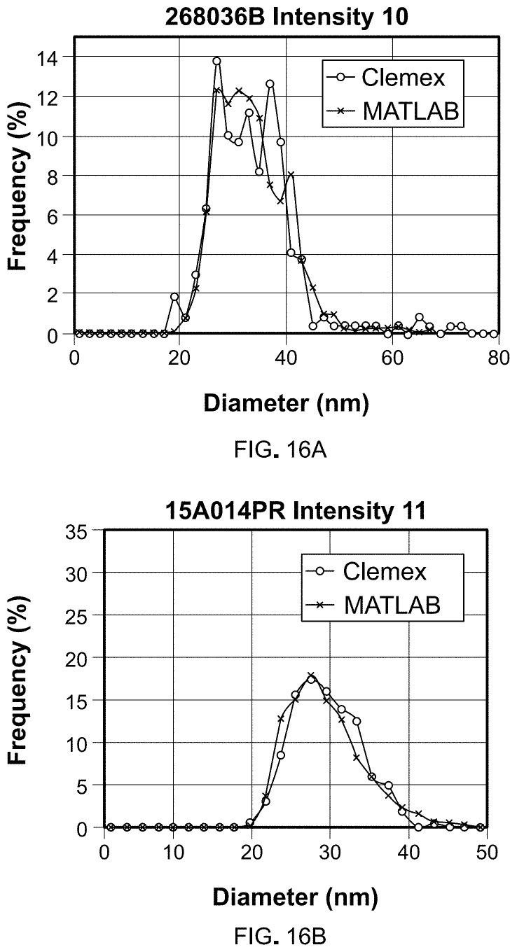

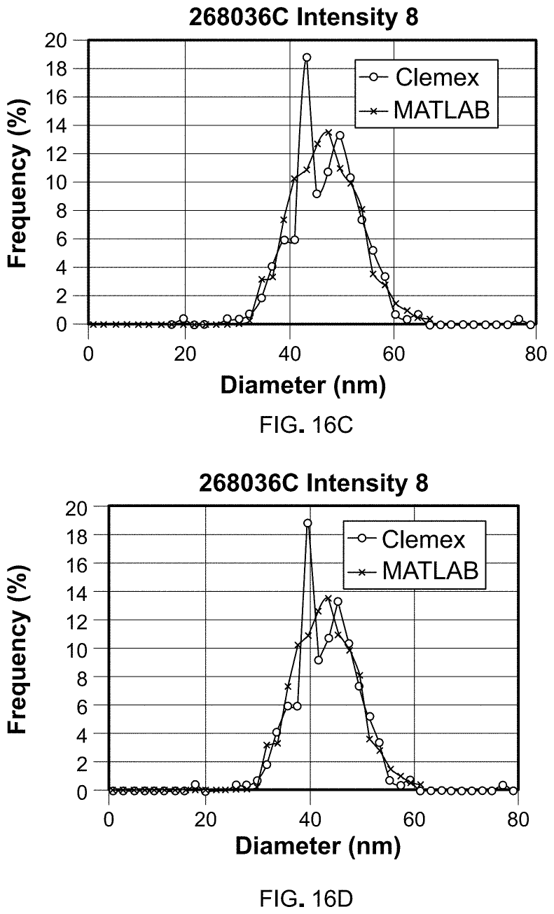

The new diameter distributions that were measured were plotted along with those measured by the SEM/CLEMEX® method to ensure they overlap when the d_{ML}/d_{SEM} scaling factor is used. These results are shown in FIGS. 16A to 16D, and it is seen that the agreement in the widths of the distributions looks very similar. To be clear, FIGS. 16A to 16D present scaled diameter data as determined using MATLAB compared with the data generated by standard methods using the SEM and CLEMEX® analysis.

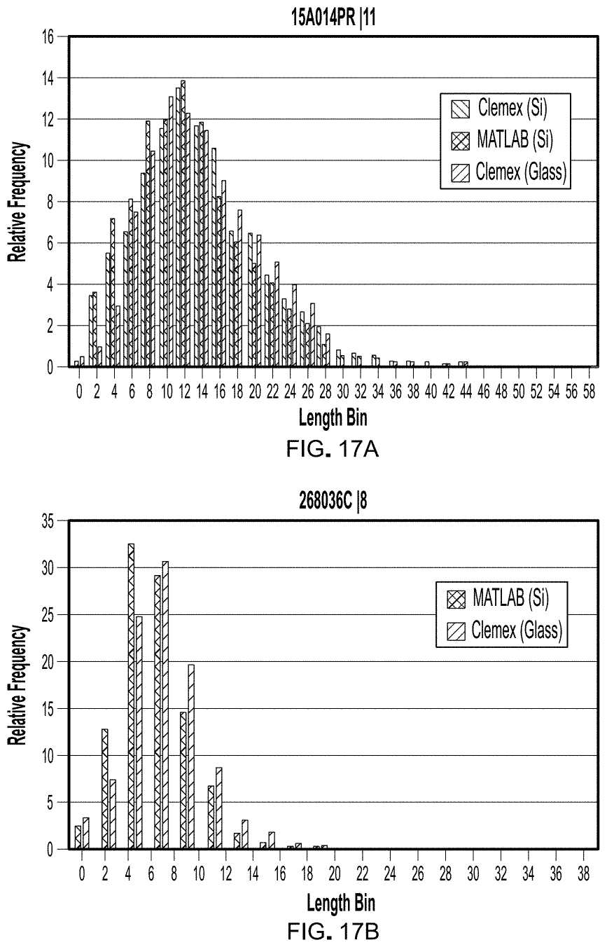

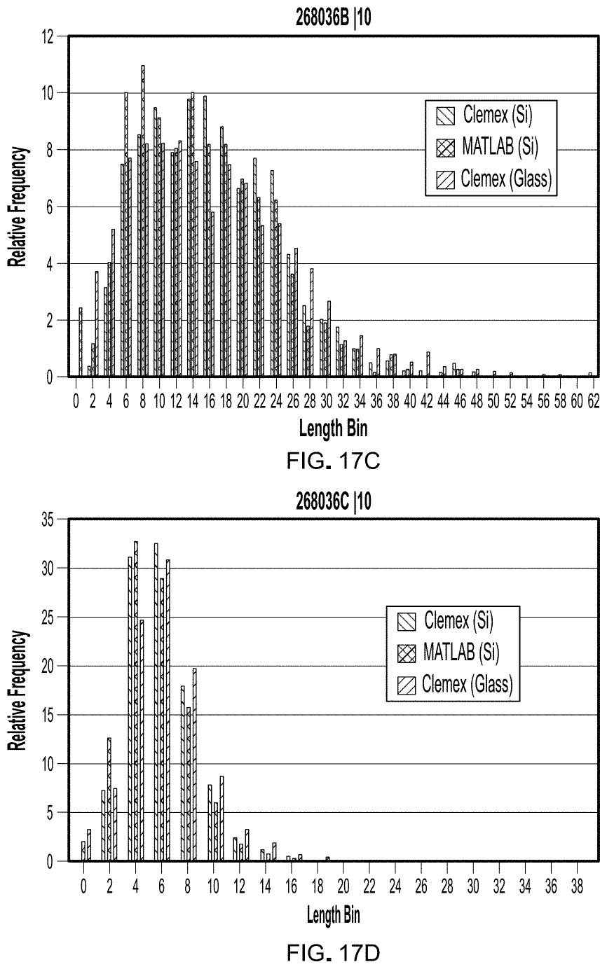

Now, an examination of the measurements of the length by the various methods shown in Table 8, below. As before, the lengths measured by the MATLAB analysis are shorter by 5-10% relative to the analysis carried out by the standard CLEMEX measurements taken when the batches were made. However, there was also less difference in this case between the CLEMEX® data on Si and the CLEMEX® data. The distributions are all plotted in FIGS. 17A-17D, which presents plots of length distributions determined using different methods. The intensity measurements refer to the Si data only. As before, the greater preponderance of data at smaller length is evident on the data taken on Si wafers.

TABLE 8
Length Averages for Additional Batches

| Batch | Clemex on Glass | Clemex on Si | Matlab on Si | Intensity |
|---|---|---|---|---|
| 15A014 | 15.7 | 15.0 | 13.9 | 11 |
| 268036B | 17.1 | 17.4 | 16.3 | 10 |
| 268036C | 7.2 | 7.0 | 6.5 | 10 |
| 268036C | 7.2 | No Data | 6.5 | 8 |

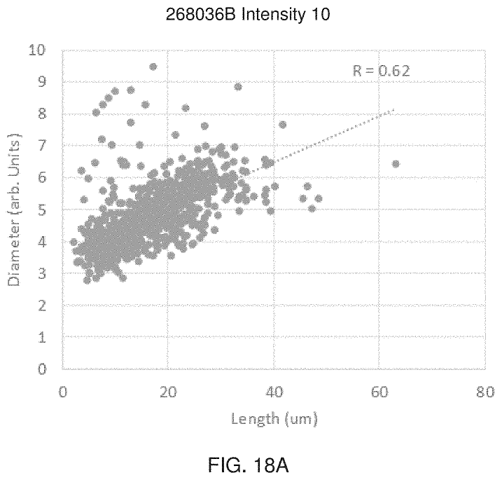

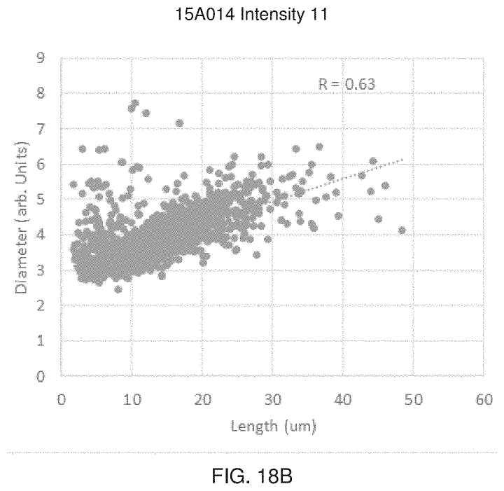

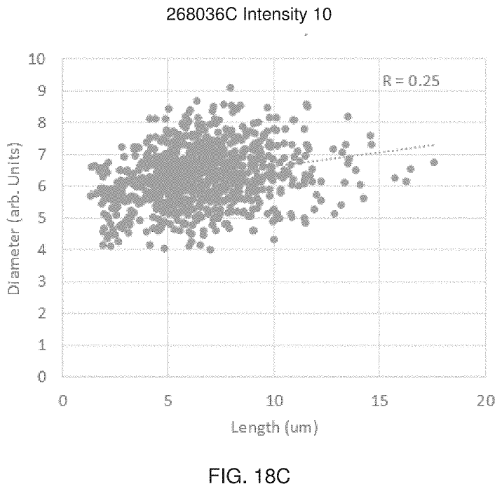

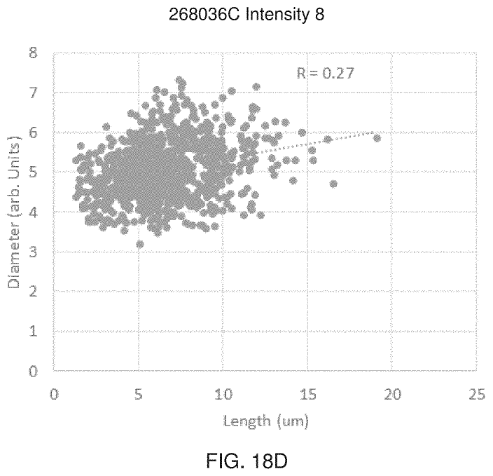

As the final part of the discussion of this data on the new nanowire batches, we look at the correlation data for length and diameter. See FIGS. 18A-18D, which present length diameter correlations for the wire batches studied. As presented above, the correlations are apparent (the correlation factor R is shown on the graphs) though as before the correlation is stronger for the thinner diameter nanowires.

An experiment was also performed upon samples. Specifically, the experiment was performed on samples where the nanowires were covered by an organic overcoat. Such was done to consider whether difference in d_{ML}/d_{SEM} observed between the different nanowire types could be due to the difference in the thickness of organic material surrounding the wires. It was taken that the organic material has an index of refraction of roughly 1.5. Therefore, if the difference in scattering is due to the thickness of this n=1.5 layer covering the wires, the difference in scattering would presumably disappear if the wires were covered by an overcoat of index n=1.5. The overcoat chosen was PMMA. It was spun on at 500 RPM for 30 s and 1500 RPM for 90 s. The resulting overcoat was measured on the KLA Tencor to be 0.63 μm thick. Performing the same analysis which has been detailed previously the results are presented within Table 9, following. One change was made to the protocol, which is that since the lighting was less than the full intensity the CLEMEX® on Si photographs were taken with an integration time of 100 ms rather than the 70 ms used previously.

TABLE 9

| | SF = d_{SEM}/d_{ML} | SF = d_{SEM}/d_{ML} | | | SF = d_{SEM}/d_{ML} | SF = d_{SEM}/d_{ML} | |
|---|---|---|---|---|---|---|---|
| Light | 15A0014 | 15A0014 | | Light | 268036D | 268036D | |
| Intensity | no PMMA | with PMMA | SF_{PMMA}/SF_{No PMMA} | Intensity | no PMMA | with PMMA | SF_{PMMA}/SF_{No PMMA} |
| 10 | 7.91 | 12.12 | 1.53 | 10 | 7.04* | 10.28 | 1.46 |
| 11 | 8.09* | 11.75 | 1.45 | | | | |

The * in Table 9 refers to data taken from the discussions above.

From the data, it was determined that for both wire types the scaling factor changed by a factor of 1.5. It is not surprising that the SF changed since the refractive index of the overcoat will change the coupling of the light into the microscope objective. However, covering the nanowires in an overcoat did not change their relative scattering powers. It therefore does not appear that the scattering difference can be explained by a difference in the thickness of the organic covering.

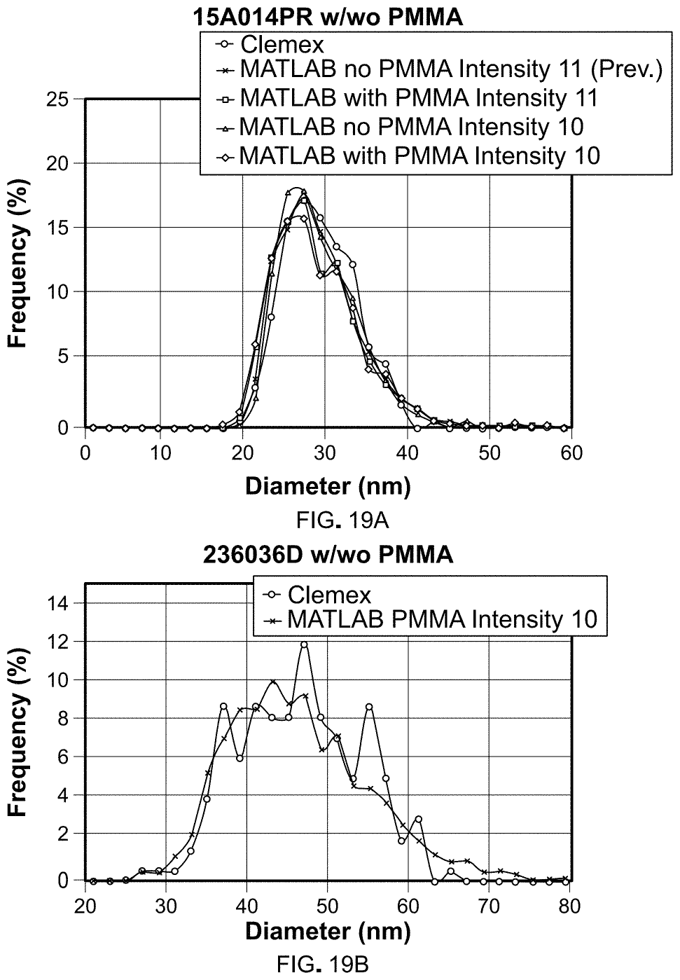

As a final check on the quality of this data, the length and width distributions are plotted within FIGS. 19A and 19B. It is seen that, taking the scaling factors into account, the new data still matches the width distribution of the standard CLEMEX® diameter data. In addition, the length distributions can be described in much the same fashion as earlier results, with the MATLAB results falling consistently below that of both the CLEMEX® on glass results and CLEMEX® on Si results. It is noted that in some cases the number of wires for the Si trials detected by the CLEMEX® routine was lower than that for the MATLAB routine, which may suggest that the CLEMEX routine was missing some of the shorter thinner wires. So, the information within FIGS. 19A and 19B demonstrates agreement in width of the nanowire diameter distributions as determined by the SEM+CLEMEX® standard technique and the newly developed MATLAB measurement technique.

Table 10 is a summary of length results in comparison with those from standard CLEMEX® on glass results and some previous work.

TABLE 10

| | | Light | Meas. | | Length | St. Dev. |
|---|---|---|---|---|---|---|
| Batch | PMMA | intensity | Method | # Wires | (μm) | Length |
| 15A0014 | No | Full | CLEMEX® | 2566 | 15.7 | 7.2 |
| | | | on Glass | | | |
| 15A0014 | No | 10 | CLEMEX® | 1249 | 15.1 | 6.7 |
| | | | on Si | | | |
| 15A0014 | No | 10 | MATLAB | 1249 | 14.5 | 6.8 |
| | | | on Si | | | |
| 15A0014 | No | 11 | CLEMEX® | 1533 | 15.0 | 7.1 |
| | | | on Si | | | |
| 15A0014 | No | 11 | MATLAB | 1524 | 13.9 | 6.8 |
| | | | on Si | | | |
| 15A0014 | Yes | 10 | CLEMEX® | 585 | 16.3 | 7.8 |
| | | | on Si | | | |
| 15A0014 | Yes | 10 | MATLAB | 1066 | 14.5 | 6.3 |
| | | | on Si | | | |
| 15A0014 | Yes | 11 | CLEMEX® | 855 | 15.6 | 7.3 |
| | | | on Si | | | |
| 15A0014 | Yes | 11 | MATLAB | 1079 | 14.5 | 6.2 |
| | | | on Si | | | |
| 268038D | No | Full | CLEMEX® | 2381 | 8.4 | 3.4 |
| | | | on Glass | | | |
| 268038D | No | 10 | CLEMEX® | 777 | 7.9 | 2.7 |
| | | | on Si | | | |
| 268038D | No | 10 | MATLAB | 792 | 7.5 | 2.6 |
| | | | on Si | | | |
| 268038D | Yes | 10 | CLEMEX® | 2403 | 7.7 | 2.8 |
| | | | on Si | | | |
| 268038D | Yes | 10 | MATLAB | 2161 | 7.3 | 2.7 |
| | | | on Si | | | |

Turning back to the example that employs a spin coater and a microscope, the following is provided as further information concerning such an example.

As mentioned, determination of at least one of lengths and diameters for all the nanowires within the population from the ink is part of the methodology of this disclosure. Also, as mentioned any process to determine at least one of lengths and diameters for all the nanowires can be utilized. As mentioned, an example includes the use of a spin coater and a microscope, with the microscope in reflected light, dark field mode, are utilized. For information regarding such an example, the following is provided.

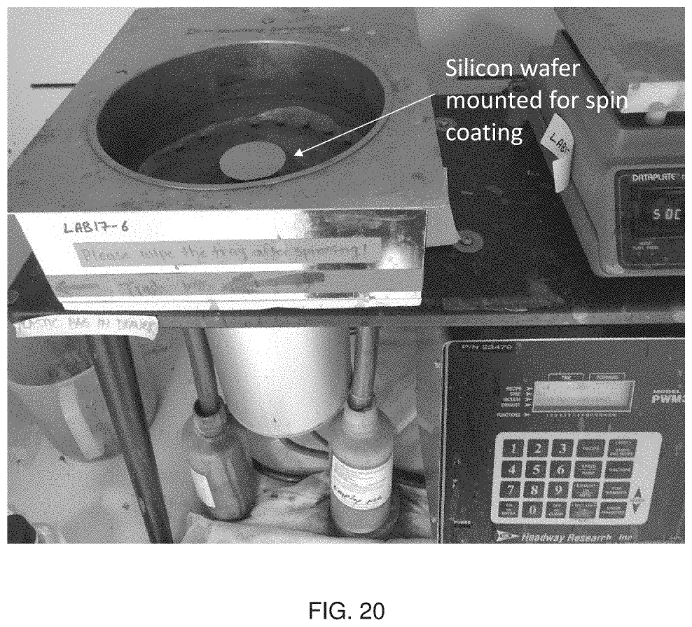

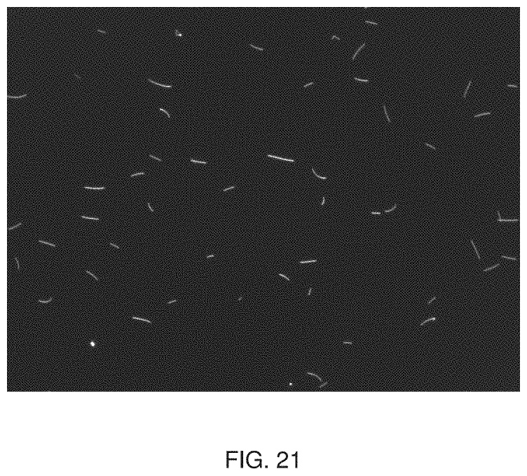

Turning back to the example that employs a spin coater and a microscope, the following is provided as further information concerning such an example. A spin coater, such as the example shown within FIG. 20, can be utilized. A dilute concentration of nanowires dissolved in IPA at 1000 RPM for 30 seconds can be spun on a silicon (Si) wafer. In an example, Si wafers are used because the images taken for nanowires on silicon provide better contrast than those taken for nanowires spun on other substrates such as glass. The concentration of nanowires in the solution is a function of the desired density of nanowires on the Si wafer. A typical image of nanowires on the surface is shown in FIG. 21.

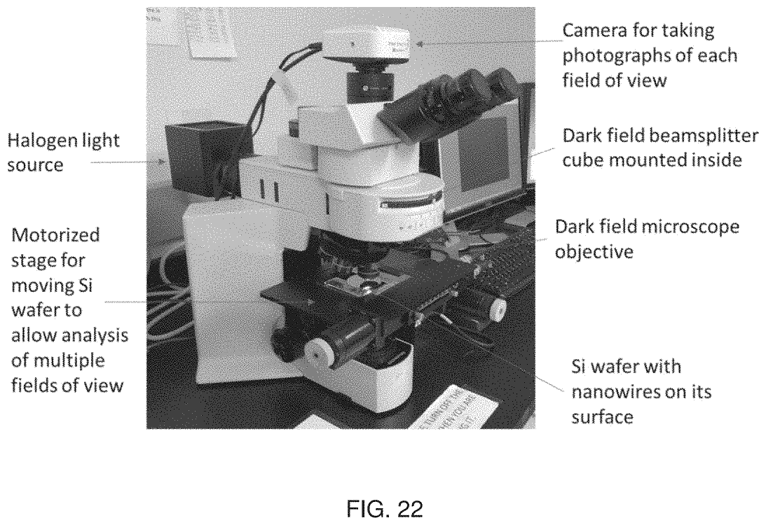

A microscope, such as the example shown within FIG. 22, can be utilized. For the shown example, the microscope is utilized in reflected light, dark field mode. The shown example is equipped with a motorized stage. Typically, images can be taken of 144 different fields of view on the Si wafer at 500× using a 50× objective. The microscope can be controlled by software which, at each field of view, takes and saves the photographs of the field of view, e.g., in TIF format, using a range of integration times. Depending on the type of nanowire being observed, these times may range from 10-100 ms, or 20-200 ms, or even include integration times as high as 300 or 400 ms for nanowires which have very small diameters and scatter very little light. Shorter (or longer) integration times could be used for very large (or small) diameter nanowires if desired.

With regard to the topic of possible variation of the integration time, the following is noted. Since the amount of light scattered by nanowires varies as a function of their diameter, some nanowires scatter light much more strongly than others. There must be enough light collected to be able to see the nanowire. Dim nanowires require long integration times. Also, intensity of any saturated pixels associated with the image of a nanowire cannot be measured. If the pixel in an image is saturated, meaning, for instance, it has the value 255 on a gray scale camera where 0 means no light and 255 is white, the true intensity of this pixel cannot be determined. The signal at this pixel might be 255 or it might be “off-scale.” Accordingly, since true value cannot be known, that particular nanowire not be analyzed. It is possible to use data from an image with a shorter integration time and look if the pixels creating the image of the nanowire are no longer saturated. If a nanowire can be observed and has an intensity which is not saturated at multiple integration times, this data can be averaged.

The data is then analyzed. Within an example, a software program could be used to perform such analysis. Such software calculates the length of all the nanowires using image analysis algorithms, but then additionally calculates the diameter of the nanowires according to the following protocol:

a) Determine the background intensity in the image.

b) Determine the integrated intensity in a box which extends ten pixels beyond the limits for each given nanowire. Subtract out the background intensity from this total.

c) Reject all nanowires which: 1) have oversaturated pixels, 2) are too close to other wires such that their integrated intensity includes contributions from other wires, 3) have an aspect ratio less than three, or 4) intersect with the edge of the image.

d) Using the background-subtracted integrated intensity and length measured for the nanowires, calculate a relative diameter using the relationship the relationship: dα(Intensity/Length)^{1/3}. Again, the value of the exponent within the example can be varied, as discussed.

Again, different methodology, structures, etc. could be used to determining at least one of lengths and diameters for all the nanowires within the population from the ink. Such different methodology, structures, etc. to determining at least one of lengths and diameters is contemplated and is to be considered within the scope of the present disclosure.

Accordingly, the present disclosure provides a new technique to method of determining length and diameter of conductive nanowires. Such measurements can occur concurrently, and optionally simultaneously. The technique of measuring diameter this way simultaneously allows correlation of length-diameter data for individual nanowires.

Unless specified otherwise, “first,” “second,” and/or the like are not intended to imply a temporal aspect, a spatial aspect, an ordering, etc. Rather, such terms are merely used as identifiers, names, etc. for features, elements, items, etc. For example, a first object and a second object generally correspond to object A and object B or two different or two identical objects or the same object.

Moreover, “example” is used herein to mean serving as an instance, illustration, etc., and not necessarily as advantageous. As used herein, “or” is intended to mean an inclusive “or” rather than an exclusive “or.” In addition, “a” and “an” as used in this application are generally be construed to mean “one or more” unless specified otherwise or clear from context to be directed to a singular form. Also, at least one of A and B and/or the like generally means A or B or both A and B. Furthermore, to the extent that “includes,” “having,” “has,” “with,” and/or variants thereof are used in either the detailed description or the claims, such terms are intended to be inclusive in a manner similar to the term “comprising.”

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing at least some of the claims.

Various operations of embodiments are provided herein. The order in which some or all of the operations are described herein should not be construed as to imply that these operations are necessarily order dependent. Alternative ordering will be appreciated by one skilled in the art having the benefit of this description. Further, it will be understood that not all operations are necessarily present in each embodiment provided herein. Also, it will be understood that not all operations are necessary in some embodiments.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method of concurrently determining length and diameter of nanowires, the method comprising:
providing the nanowires onto a support;
providing a chosen illumination of the nanowires on the support;
obtaining an image of the nanowires on the support;
calculating a length of each nanowire by an image processing program; and
calculating a relative diameter of each nanowire based on an integrated intensity of light scattered per unit length from each nanowire.

2. The method as set forth in claim 1, wherein the step of calculating the relative diameter includes using the following equation:
relative diameter α(subtracted value/length)ⁿ.

3. The method as set forth in claim 2, wherein a value of n is within a range of ⅕ to ½.

4. The method as set forth in claim 3, wherein the value of n is approximately ⅓.

5. The method as set forth in claim 4, wherein the value of n is ⅓.

6. The method as set forth in claim 1, including determining a background intensity value for the image of the nanowires.

7. The method as set forth in claim 6, including determining the integrated intensity value for each nanowire for a pixel box that extends a selected number of pixels beyond the respective nanowire.

8. The method as set forth in claim 7, including subtracting the background intensity from the determined integrated intensity to determine a subtracted value for each nanowire.

9. The method as set forth in claim 1, wherein the method is used to concurrently determining length and diameter of nanowires.

10. The method as set forth in claim 1, wherein the nanowires include electrically conductive material.

11. The method as set forth in claim 1, wherein electrically conductive material of the nanowires includes silver.

12. The method as set forth in claim 1, wherein the step of providing the nanowires onto a support includes using a spin coater.

13. The method as set forth in claim 1, including using a microscope.

14. The method as set forth in claim 13, wherein the microscope is used in a reflected light, dark field mode.

15. The method as set forth in claim 1, wherein length and diameter are not determined for any nanowire in which the image has an oversaturated pixel within a pixel box for the nanowire.

16. The method as set forth in claim 1, wherein length and diameter are not determined for any nanowire in which the nanowire is too close to another nanowire such that the integrated intensity includes contributions from the other nanowire.

17. The method as set forth in claim 1, wherein length and diameter are not determined for any nanowire in which the nanowire has an aspect ratio less than three.

18. The method as set forth in claim 1, wherein length and diameter are not determined for any nanowire in which the nanowire intersects with an edge of the image.
